(19) United States
(12) Patent Application Publication
(10) Pub. No.: US 2025/0183611 A1
(43) Pub. Date: Jun. 5, 2025

(54) LASER DEVICE AND ELECTRONIC DEVICE MANUFACTURING METHOD

(71) Applicant: Gigaphoton Inc., Tochigi (JP)

(72) Inventors: Keita KOUZAI, Oyama-shi (JP); Masanori YASHIRO, Oyama-shi (JP)

(73) Assignee: Gigaphoton Inc., Tochigi (JP)

(21) Appl. No.: 19/044,083

(22) Filed: Feb. 3, 2025

Related U.S. Application Data
(63) Continuation of application No. PCT/JP2022/033128, filed on Sep. 2, 2022.

(51) Int. Cl. H01S 3/081; G03F 7/00

(52) U.S. Cl. CPC H01S 3/0813; G03F 7/70025; G03F 7/70041

(57) ABSTRACT

A laser device includes a pair of electrodes configured to cause discharge to occur, and an optical pulse stretcher configured to extend a pulse width of pulse laser light generated by the discharge having occurred between the electrodes. Here, the optical pulse stretcher includes a beam splitter arranged such that an optical surface thereof on which the pulse laser light is incident is inclined with respect to an optical path axis of the pulse laser light, and configured to separate the pulse laser light incident on the optical surface into reflection laser light and transmission laser light; a plurality of mirrors configured to guide the reflection laser light to the beam splitter; and a slide mechanism configured to move the beam splitter in a direction perpendicular to a direction of the discharge and parallel to the optical surface.

### CROSS-REFERENCE TO RELATED APPLICATIONS

The present application claims the benefit of International Application No. PCT/JP2022/033128, filed on Sep. 2, 2022, the entire contents of which are hereby incorporated by reference.

### BACKGROUND

### 1. Technical Field

The present disclosure relates to a laser device and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: U.S. Pat. No. 10,585,215
Patent Document 2: US Patent Application Publication No. 2018/0019141
Patent Document 3: Japanese Patent Application Publication No. H10-144987
Patent Document 4: U.S. Pat. No. 7,415,056

### SUMMARY

A laser device according to an aspect of the present disclosure includes a pair of electrodes configured to cause discharge to occur, and an optical pulse stretcher configured to extend a pulse width of pulse laser light generated by the discharge having occurred between the electrodes. Here, the optical pulse stretcher includes a beam splitter arranged such that an optical surface thereof on which the pulse laser light is incident is inclined with respect to an optical path axis of the pulse laser light, and configured to separate the pulse laser light incident on the optical surface into reflection laser light and transmission laser light; a plurality of mirrors configured to guide the reflection laser light to the beam splitter; and a slide mechanism configured to move the beam splitter in a direction perpendicular to a direction of the discharge and parallel to the optical surface.

An electronic device manufacturing method according to another aspect of the present disclosure includes generating laser light with a pulse width extended using a laser device, outputting the laser light to an exposure apparatus, and exposing a photosensitive substrate to the laser light in the exposure apparatus to manufacture an electronic device. Here, the laser device includes a pair of electrodes configured to cause discharge to occur, and an optical pulse stretcher configured to extend the pulse width of pulse laser light generated by the discharge having occurred between the electrodes. The optical pulse stretcher includes a beam splitter arranged such that an optical surface thereof on which the pulse laser light is incident is inclined with respect to an optical path axis of the pulse laser light, and configured to separate the pulse laser light incident on the optical surface into laser reflection light and transmission laser light; a plurality of mirrors configured to guide the reflection laser light to the beam splitter; and a slide mechanism configured to move the beam splitter in a direction perpendicular to a direction of the discharge and parallel to the optical surface.

### BRIEF DESCRIPTION OF THE DRAWINGS

Embodiments of the present disclosure will be described below merely as examples with reference to the accompanying drawings.

FIG. 1 schematically shows an exemplary configuration of a laser device.

FIG. 2 is a perspective view showing another example of an optical pulse stretcher (OPS).

FIG. 3 is a perspective view showing a state in which a maintenance panel of a housing of the laser device is opened.

FIG. 4 schematically shows a main part of a slide mechanism of a beam splitter applied to the OPS of the laser device according to a first embodiment.

FIG. 5 is a side view including a partial section of the slide mechanism shown in FIG. 4.

FIG. 6 is a view showing a state in which the beam splitter is arranged at a first position by the slide mechanism.

FIG. 7 is a view showing a state in which the beam splitter is arranged at a second position by the slide mechanism.

FIG. 8 is a sectional view taken along line 8-8 of FIG. 7.

FIG. 9 schematically shows a main part of the slide mechanism of the beam splitter applied to the OPS of the laser device according to a second embodiment.

FIG. 10 is a side view including a partial section of the slide mechanism shown in FIG. 9.

FIG. 11 is a view showing a state in which the beam splitter is arranged at the first position by the slide mechanism.

FIG. 12 is a view showing a state in which the beam splitter is arranged at the second position by the slide mechanism.

FIG. 13 is a sectional view taken along line 13-13 of FIG. 12.

FIG. 14 is a view schematically showing a main part of the slide mechanism applied to the OPS of the laser device according to a third embodiment.

FIG. 15 is a side view including a partial section of the slide mechanism.

FIG. 16 is a view schematically showing a main part of the slide mechanism applied to the OPS of the laser device according to a fourth embodiment.

FIG. 17 is a side view including a partial section of the slide mechanism shown in FIG. 16.

FIG. 18 is a perspective view schematically showing the configuration of the OPS applied to the laser device according to a fifth embodiment.

FIG. 19 is an explanatory diagram of a calculation expression for determining a shift amount of a light beam by a transmission element.

FIG. 20 schematically shows a configuration example of an exposure apparatus.

### DESCRIPTION OF EMBODIMENTS

### Contents

1. Overview of laser device
   1.1 Configuration
   1.2 Operation
2. Another example of OPS
   2.1 Configuration
   2.2 Operation
2.3 Effect
3. Problem
4. First Embodiment
   4.1 Configuration
   4.2 Operation
   4.3 Effect
5. Second Embodiment
   5.1 Configuration
   5.2 Operation
   5.3 Effect
6. Third Embodiment
   6.1 Configuration
   6.2 Operation
   6.3 Effect
   6.4 Modification
7. Fourth Embodiment
   7.1 Configuration
   7.2 Operation
   7.3 Effect
   7.4 Modification
8. Fifth Embodiment
   8.1 Configuration
   8.2 Operation
   8.3 Effect
   8.4 First modification
   8.5 Second modification
9. Modification of laser device
10. Electronic device manufacturing method
11. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overview of Laser Device

### 1.1 Configuration

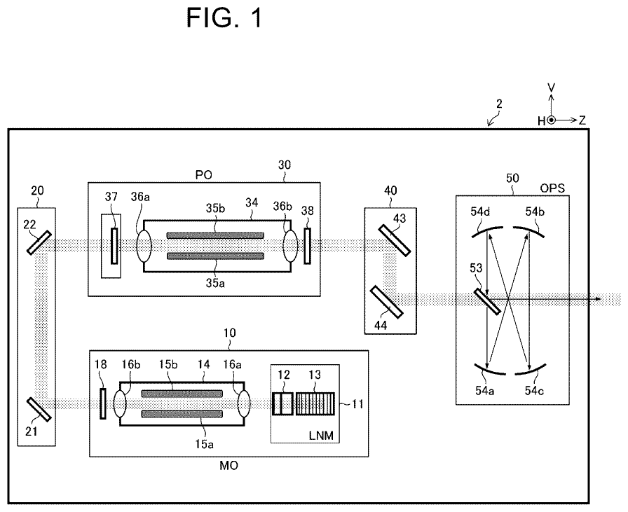

FIG. 1 schematically shows an exemplary configuration of a laser device 2. The laser device 2 is an excimer laser device including a master oscillator (MO) 10, an MO beam steering unit 20, a power oscillator (PO) 30, a PO beam steering unit 40, and an optical pulse stretcher (OPS) 50.

The MO 10 includes an LNM 11, a chamber 14, and an output coupling mirror (OC) 18. The LNM 11 includes a prism beam expander 12 for narrowing the spectral line width and a grating 13. The prism beam expander 12 and the grating 13 are arranged in the Littrow arrangement so that an incident angle and a diffraction angle coincide with each other.

The OC 18 is a partial reflection mirror and is arranged to configure an optical resonator together with the LNM 11. The reflectance of the OC 18 may be, for example, between 40% and 60%.

The chamber 14 is arranged on the optical path of the optical resonator. The chamber 14 includes a pair of discharge electrodes 15a, 15b and two windows 16a, 16b through which laser light passes. An excimer laser gas is introduced into the chamber 14. The excimer laser gas includes, for example, an Ar gas or a Kr gas as a rare gas, an F₂ gas as a halogen gas, and an Ne gas as a buffer gas.

The MO beam steering unit 20 includes a high reflection mirror 21 and a high reflection mirror 22, and is arranged such that the pulse laser light output from the MO 10 enters the PO 30.

The PO 30 includes a rear mirror 37, a chamber 34, and an OC 38. The rear mirror 37 and the OC 38 configure an optical resonator, and the chamber 34 is arranged on the optical path of the optical resonator.

The configuration of the chamber 34 may be similar to that of the chamber 14. That is, the chamber 34 includes a pair of discharge electrodes 35a, 35b and two windows 36a, 36b through which the laser light passes. An excimer laser gas is introduced into the chamber 34. The rear mirror 37 is a partial reflection mirror having a reflectance of 50% to 90%. The OC 38 is a partial reflection mirror having a reflectance of 10% to 30%.

The PO beam steering unit 40 includes a high reflection mirror 43 and a high reflection mirror 44. These high reflection mirrors 43, 44 are arranged such that the pulse laser light output from the PO 30 enters the OPS 50.

The OPS 50 includes a beam splitter 53 and four concave mirrors 54a, 54b, 54c, 54d. The beam splitter 53 is arranged on the optical path of the pulse laser light output from the PO beam steering unit 40. The beam splitter 53 is a partial reflection mirror that transmits a part of the pulse laser light of the incident pulse laser light and reflects the other part thereof. That is, the beam splitter 53 separates the pulse laser light incident thereon into reflection laser light and transmission laser light. The reflectance of the beam splitter 53 may be, for example, 60%. The beam splitter 53 causes the pulse laser light transmitted through the beam splitter 53 to be output from the laser device 2.

The four concave mirrors 54a to 54d configure a delay optical path of the pulse laser light reflected by a first surface of the beam splitter 53. The pulse laser light reflected by the first surface of the beam splitter 53 is reflected by the four concave mirrors 54a to 54d, and is focused again on the beam splitter 53.

The four concave mirrors 54a to 54d may be concave mirrors having substantially the same focal length. The focal length f of each of the concave mirrors 54a to 54d may correspond to, for example, the distance from the beam splitter 53 to the concave mirror 54a.

The concave mirror 54a and the concave mirror 54b are arranged such that the pulse laser light reflected by the first surface of the beam splitter 53 is reflected by the concave mirror 54a to be incident on the concave mirror 54b. The concave mirror 54a and the concave mirror 54b are arranged such that the pulse laser light reflected by the first surface of the beam splitter 53 is focused as a first image at magnification (1:1) equal to the image on the first surface of the beam splitter 53.

The concave mirror 54c and the concave mirror 54d are arranged such that the pulse laser light reflected by the concave mirror 54b is reflected by the concave mirror 54c to be incident on the concave mirror 54d. Further, the concave mirror 54d is arranged such that the pulse laser light reflected by the concave mirror 54d is incident on a second surface of the beam splitter 53 on the side opposite to the first surface. The concave mirror 54c and the concave mirror 54d are arranged such that the first image is focused on the second surface of the beam splitter 53 at 1:1 as a second image. The four concave mirrors 54a to 54d are an example of the “plurality of mirrors” in the present disclosure.

### 1.2 Operation

When discharge occurs in the chamber 14 of the MO 10, the laser gas is excited, and the pulse laser light line-narrowed by the optical resonator configured by the OC 18 and the LNM 11 is output from the OC 18. The pulse laser light is incident on the rear mirror 37 of the PO 30 as seed light by the MO beam steering unit 20.

Discharge occurs in the chamber 34 in synchronization with the timing when the seed light transmitted through the rear mirror 37 enters. As a result, the laser gas is excited, the seed light is amplified by the Fabry-Perot optical resonator configured by the OC 38 and the rear mirror 37, and the amplified pulse laser light is output from the OC 38. The pulse laser light output from the OC 38 enters the OPS 50 via the PO beam steering unit 40. The pulse width of the pulse laser light is extended by the OPS 50.

The pulse laser light having passed through the OPS 50 may pass through a monitor module (not shown) and enter a beam characteristic measurement device. The monitor module is a module that measures the pulse energy, spectral line width, wavelength, and the like. The beam characteristic measurement device is a module that measures the pointing, divergence, polarization degree, and the like. Although FIG. 1 shows an example in which the OPS 50 as one stage is provided, the laser device 2 may include OPSs as two or more stages. For example, one or more OPSs (not shown) may be arranged in series on the optical path of the pulse laser light output from the OPS 50.

### 2. Another Example of OPS

### 2.1 Configuration

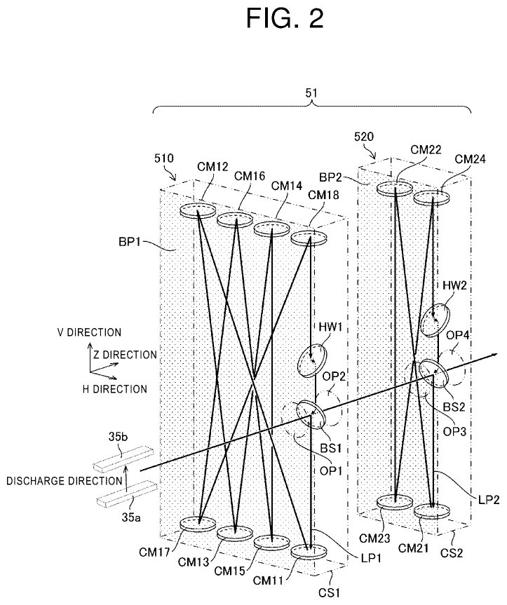

FIG. 2 is a perspective view showing another example of the OPS. Instead of the OPS 50 shown in FIG. 1, an OPS 51 having a two-stage configuration as shown in FIG. 2 may be employed.

The OPS 51 includes a first OPS module 510 and a second OPS module 520. The first OPS module 510 includes a beam splitter BS1, a loop optical path LP1, and a case CS1 including a base plate BP1. The loop optical path LP1 is a delay optical path configured by concave mirrors CM11 to CM18 and a halving window HW1.

The second OPS module 520 is configured by a beam splitter BS2, a loop optical path LP2, and a case CS2 including a base plate BP2. The loop optical path LP2 is a delay optical path configured by concave mirrors CM21 to CM24 and a halving window HW2.

Each optical element is held by a holder (not shown), and the holders are positioned on the base plates BP1, BP2, respectively. Each of the base plates BP1, BP2 may configure any surface of the corresponding case CS1, CS2, but in the example shown in FIG. 2, the base plates BP1, BP2 configure surfaces parallel to an HV plane on the front side of the cases CS1, CS2. The discharge direction of the discharge electrodes 35a, 35b is represented by the V direction, and a direction parallel to the optical path axis of the laser light entering the OPS 51 is represented by the Z direction. The direction perpendicular to both the V direction and the Z direction is represented by the H direction. The discharge electrodes 35a, 35b are an example of the “pair of electrodes” in the present disclosure.

Here, in the present specification, the term “orthogonal” or “perpendicular” is not limited to the case of being strictly orthogonal or perpendicular, and includes the concept of substantially being orthogonal or substantially perpendicular including a range of angular difference that is practically acceptable without losing technical significance, unless otherwise specified. Further, in the present specification, the term “parallel” is not limited to the case of being strictly parallel, and includes the concept of being substantially parallel including a range of angular difference that is practically acceptable without losing technical significance, unless otherwise specified.

Openings OP1, OP2 through which the laser light passes is formed in the case CS1. The opening OP1 is an entrance port of the laser light to the first OPS module 510, and the opening OP2 is an outlet port of the laser light from the first OPS module 510. Similarly, an opening OP3 which is an entrance port of the laser light and an opening OP4 which is an outlet port are formed in the case CS2.

The concave mirrors CM11 to CM18, CM21 to CM24 are arranged to face each other at both ends of the cases CS1, CS2 in the V direction. That is, the concave mirrors CM11, CM15, CM13, CM17 of the first OPS module 510 are arranged in this order in a direction parallel to the H direction on the bottom side of the case CS1, and the concave mirrors CM18, CM14, CM16, CM12 are arranged in this order in a direction parallel to the H direction on the top side of the case CS1. Thus, the concave mirror CM11 is arranged to face the concave mirror CM18 across the beam splitter BS1.

Similarly, the concave mirrors CM15, CM13, CM17 are arranged to face the concave mirrors CM14, CM16, CM12, respectively. The loop optical path LP1 is configured such that the light reflected by the beam splitter BS1 returns to the beam splitter BS1 after being reflected by the concave mirrors CM11, CM12, CM13, CM14, CM15, CM16, CM17, CM18 in this order.

Further, the concave mirrors CM21, CM23 of the second OPS module 520 are arranged in this order in a direction parallel to the H direction on the bottom side of the case CS2, and the concave mirrors CM24, CM22 are arranged in this order in a direction parallel to the H direction on the top side of the case CS2. Thus, the concave mirror CM21 is arranged to face the concave mirror CM24 across the beam splitter BS2, and the concave mirror CM23 is arranged to face the concave mirror CM22. The loop optical path LP2 is configured such that the light reflected by the beam splitter BS2 returns to the beam splitter BS2 after being reflected by the concave mirrors CM21, CM22, CM23, CM24 in this order.

Each of the beam splitters BS1, BS2 is located on the optical path of the pulse laser light output from the PO beam steering unit 40.

Each of the halving windows HW1, HW2 is arranged between the corresponding final concave mirror CM18, CM24 in the loop optical path LP1, LP2 and the corresponding beam splitter BS1, BS2.

### 2.2 Operation

The pulse laser light output from the PO 30 passes through the opening OP1 and enters the beam splitter BS1. A part of the pulse laser light is transmitted and the remaining part thereof is reflected. The pulse laser light reflected by the beam splitter BS1 propagates through the loop optical path LP1 and passes through the halving window HW1 to be accurately multiplexed with the pulse laser light transmitted through the beam splitter BS1.

A part of the pulse laser light entering the beam splitter BS1 again is transmitted, and the remaining part is reflected. The reflected pulse laser light is multiplexed with the pulse laser light transmitted through the beam splitter BS1 without passing through the loop optical path LP1. As described above, the pulse laser light passing through the loop optical path LP1 is sequentially superimposed on the pulse laser light transmitted through the beam splitter BS1, whereby the pulse width is extended. The pulse laser light passing through the loop optical path LP1 is prevented, by passing through the halving window HW1, from having the optical path thereof deviated every time it propagates through the loop optical path LP1.

Similarly, the pulse laser light output from the first OPS module 510 is incident on the beam splitter BS2, and the pulse width is further extended in the process of propagating through the loop optical path LP2.

### 2.3 Effect

According to the OPS 51 shown in FIG. 2, the pulse width can be greatly extended by the loop optical path LP1 of the first stage and the loop optical path LP2 of the second stage, and occurrence of speckle can be suppressed. Further, since the pulse width is extended, an energy value per unit time radiated to an optical system at a subsequent stage is decreased, and deterioration of the optical system is suppressed.

### 3. Problem

As the power of the laser device 2 is increased, deterioration of the optical characteristics of the beam splitters 53, BS1, BS2 used for a long period of time has been observed in some cases. The deterioration of the optical characteristics is typically a decrease in the transmittance of the laser light transmitting portion or a decrease in the reflectance of the laser light reflecting portion. In such cases, the transmittance of the entire OPS 50, 51 is decreased, and the pulse waveform after passing through the OPS 50, 51 is changed.

In the laser device 2 according to the comparative example, in order to recover the transmittance, it is necessary to replace the beam splitter 53, BS1, BS2 or the like whose optical characteristics have deteriorated. The comparative example of the present disclosure is an example recognized by the applicant as known only by the applicant, and is not a publicly known example admitted by the applicant.

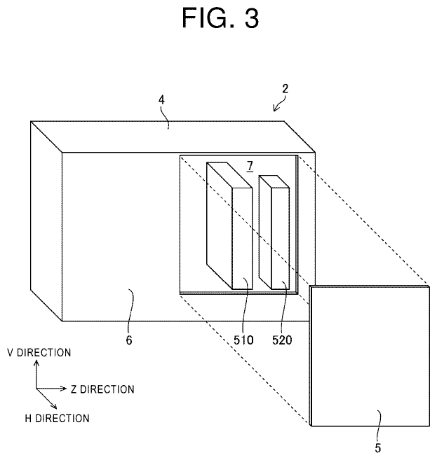

As shown in FIG. 3, a housing 4 of the laser device 2 includes a maintenance panel 5 that can be opened and closed. In the laser device 2, in order to replace only optical elements such as the beam splitter 53, BS1, BS2, the maintenance panel 5 of the housing 4 of the laser device 2 needs to be removed, and further, an optical element holder in the first OPS module 510 and/or an optical element holder in the second OPS module 520 need to be accessed, but it is difficult to carry out due to limitation of an opening 7 (maintenance opening) of a maintenance surface 6 causing poor workability.

As current maintenance operation, the first OPS module 510 and the second OPS module 520 are removed from the laser device 2 as a set product at a customer site where the laser device 2 is arranged, and are replaced with a new set followed by optical axis adjustment. Here, the OPS set removed from the laser device 2 is returned to the manufacturing plant of the laser device 2, and replacement of the deteriorated optical element therein and optical axis adjustment of the OPS alone are performed. Therefore, there are the following problems.

### Problem 1

The laser downtime at the customer site is very long for replacing the OPS set.

### Problem 2

The man-hours and/or cost for transporting the OPS set between the customer and the plant are increased.

### Problem 3

The optical elements such as the beam splitters 53, BS1, BS2 are disposable, and therefore the cost is increased.

### 4. First Embodiment

### 4.1 Configuration

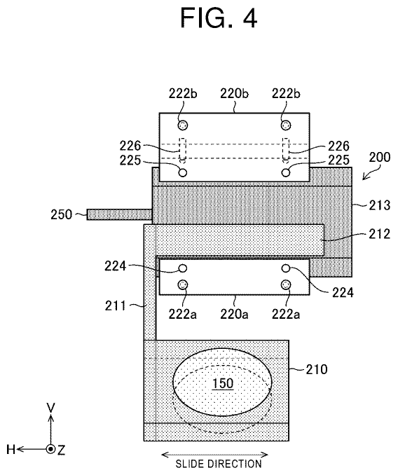

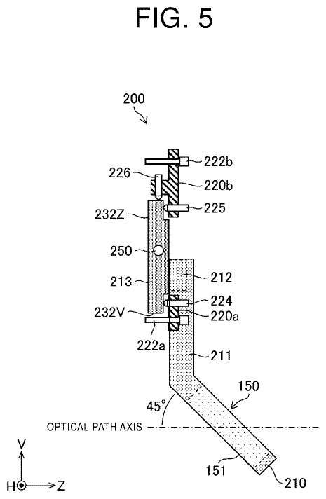

FIGS. 4 and 5 schematically show a slide mechanism 200 of a beam splitter 150 applied to the OPS of the laser device 2 according to a first embodiment. FIG. 4 is a view viewed from a direction (Z direction) parallel to the optical path axis of the laser light transmitted through the beam splitter 150, and FIG. 5 is a side view including a partial cross section viewed from a direction (H direction) perpendicular to the Z direction and the V direction. The H direction is a direction parallel to an optical surface 151 of the beam splitter 150.

The slide mechanism 200 includes a beam splitter (BS) holder 210 for holding the beam splitter 150, plates 211, 212, 213, and plate holders 220a, 220b. The beam splitter 150 may be either the beam splitter 53 shown in FIG. 1 or the beam splitters BS1, BS2 shown in FIG. 2.

The beam splitter 150 is fixed to the BS holder 210. The beam splitter 150 is arranged such that the optical surface 151 on which the laser light is incident is inclined by 45 degrees with respect to the optical path axis of the pulse laser light output from the PO beam steering unit 40.

The BS holder 210 is fixed to the plate 211. The plate 211 is fixed to the plate 212. The plate 212 is fixed to the plate 213. The plate 213 has a V-direction reference surface 232V and a Z-direction reference surface 232Z. The V-direction reference surface 232V is a surface perpendicular to the V direction and defining a reference position of the beam splitter 150 in the V direction. The Z-direction reference surface 232Z is a surface perpendicular to the Z direction and defining the reference position of the beam splitter 150 in the Z direction.

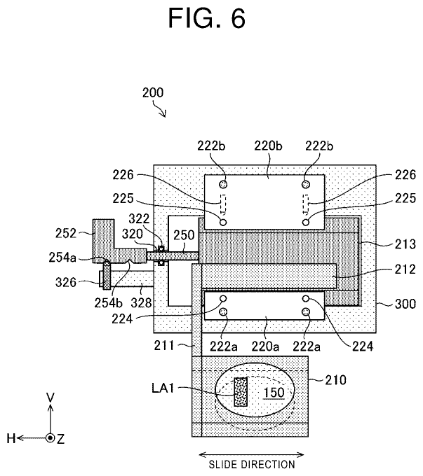

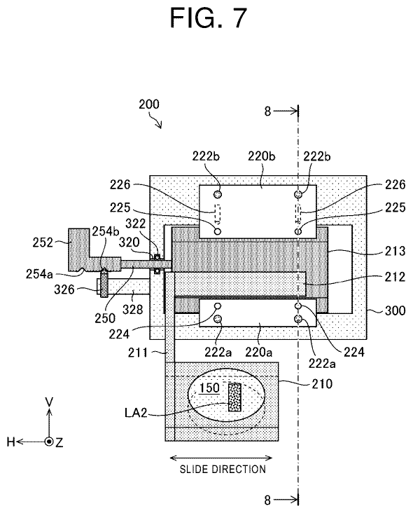

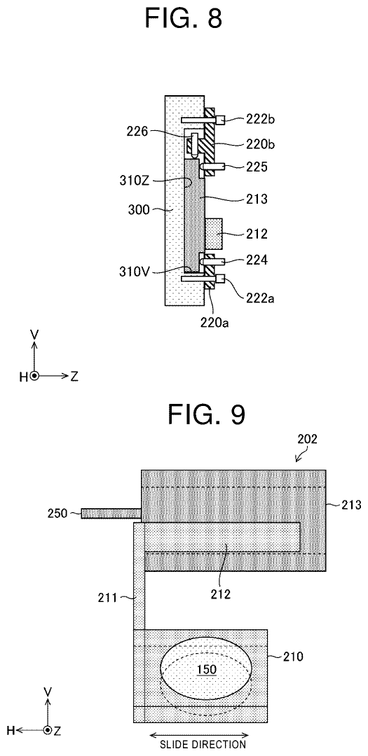

FIG. 6 is a view showing a state in which the beam splitter 150 is arranged at a first position by the slide mechanism 200. FIG. 7 is a view showing a state in which the beam splitter 150 is arranged at a second position by the slide mechanism 200. FIG. 8 is a sectional view taken along line 8-8 of FIG. 7.

The plate holders 220a, 220b are fixed to the case 300 using bolts 222a, 222b. The plate holders 220a, 220b cause the plate 213 to be in contact with the reference surfaces 310V, 310Z on the case 300 side (see FIG. 8), so that the plate 213 is held in a slidable manner along the reference surfaces 310V, 310Z. The reference surface 310V is a case reference surface perpendicular to the V direction. The reference surface 310Z is a case reference surface perpendicular to the Z direction.

The case 300 may be the case CS1 or the case CS2 shown in FIG. 2. The reference surface 310V and the reference surface 310Z may be formed on the base plate BP1 or the base plate BP2 shown in FIG. 2. The plate 213 is pressed by a reaction force of springs (not shown) arranged on plungers 224, 225, 226, and the like so that the V-direction reference surface 232V and the Z-direction reference surface 232Z of the plate 213 are reliably brought into contact with the reference surface 310V and the reference surface 310Z on the case 300 side, respectively.

The plunger 224 acting in the Z direction is attached to the plate holder 220a. The plunger 225 acting in the Z direction and the plunger 226 acting in the V direction are attached to the plate holder 220b.

The plungers 224, 225 urge the plate 213 in the direction from the right to the left in FIG. 5 (−Z direction), and press the Z-direction reference surface 232Z of the plate 213 against the reference surface 310Z of the case 300. The plunger 226 urges the plate 213 in the direction from the upside to the downside in FIG. 5 (−V direction), and presses the V-direction reference surface 232V of the plate 213 against the reference surface 310V of the case 300.

Due to the reaction force of the plungers 224, 225, 226, the V-direction reference surface 232V and the Z-direction reference surface 232Z are brought into contact with the reference surface 310V and the reference surface 310Z of the case 300, respectively, and the plate 213 can slide along the reference surface 310V and the reference surface 310Z. That is, the plate 213 is slidable in the H direction with the position in the V direction and the Z direction maintained. The H direction may be referred to as a slide direction. The plate 213 is an example of the “movable plate” in the present disclosure. The reference surface 310Z is an example of the “first reference surface” in the present disclosure, and the reference surface 232V is an example of the “second reference surface” in the present disclosure. Each of the plungers 224, 225 is an example of the “first plunger” in the present disclosure. The plunger 226 is an example of the “second plunger” in the present disclosure.

A rod 250 extending in the H direction is connected to the plate 213 so that the plate 213 can be moved in the H direction by applying a force to the plate 213 from the outside of the case 300. The rod 250 extends to the outside of the case 300 as penetrating through a through hole 320 formed in the case 300. An O-ring 322 for sealing is arranged in the through hole 320 to maintain airtightness at the case 300, and the rod 250 is movable in the H direction in contact with the O-ring 322. A handle 252 is provided at an end of the rod 250 extending to the outside of the case 300. The O-ring 322 is an example of the “seal member” in the present disclosure.

Further, the handle 252 is formed with positioning grooves 254a, 254b that define a position in the slide direction. The present embodiment shows an example in which two positioning grooves 254a, 254b corresponding to two positions being the first position (FIG. 6) and the second position (FIG. 7) are provided, but the positioning grooves corresponding to three or more positions may be provided. The positioning grooves 254a, 254b are an example of the “first recessed portion” and the “second recessed portion” in the present disclosure.

A plunger 326 used for positioning in the slide direction is arranged at the case 300. The plunger 326 is fixed to a support member 328 extending from the case 300. The plunger 326 engages with either one of the positioning grooves 254a, 254b to perform positioning of the plate 213 in the H-direction position, that is, positioning of the beam splitter 150 in the H-direction position. The plunger 326 is an example of the “positioning plunger” in the present disclosure. The positioning mechanism including the positioning grooves 254a, 254b and the plunger 326 is an example of the “positioning mechanism” in the present disclosure. The handle 252 having the positioning grooves 254a, 254b is an example of the “engaged member” in the present disclosure.

### 4.2 Operation

The plate 213 slides in a direction perpendicular to the optical path axis (Z axis) and parallel to the optical surface 151 of the beam splitter 150, so that the laser irradiation position on the beam splitter 150 can be shifted while the orientation of is the optical surface 151 maintained. The direction parallel to the optical surface 151 of the beam splitter 150 may be a direction intersecting the maintenance surface 6 or a direction passing through the maintenance opening 7.

As shown in FIG. 6, by engaging the plunger 326 with the positioning groove 254a of the handle 252, the plate 213 and the beam splitter 150 which is integrally slidable with the plate 213 are positioned at the first position.

Further, a field engineer or the like operates the handle 252 to pull out the rod 250 from the state of FIG. 6, and causes the plunger 326 to engage with the positioning groove 254b of the handle 252 as shown in FIG. 7, whereby the plate 213 and the beam splitter 150 are positioned at the second position.

It is preferable to set a movement amount (slide amount) in the slide direction by the slide mechanism 200 so that an irradiation region LA1 of the laser light with respect to the beam splitter 150 at the first position and an irradiation region LA2 of the laser light with respect to the beam splitter 150 at the second position do not overlap.

For example, the laser device 2 is first used with the beam splitter 150 being at the first position, and when optical characteristics of a part of the region of the beam splitter 150 are deteriorated due to the laser irradiation on the beam splitter 150, the beam splitter 150 is moved to the second position so that another region that is not deteriorated is irradiated with the laser light.

### 4.3 Effect

The beam splitter 150 is deteriorated (energy transmittance is deteriorated) due to the laser irradiation. According to the configuration of the first embodiment, by moving the beam splitter 150 by the slide mechanism, the laser irradiation position with respect to the beam splitter 150 can be shifted, and a position not deteriorated can be irradiated with the laser light. Thus, by using the beam splitter 150 while avoiding the deteriorated position, the frequency of replacement can be reduced, and a long lifetime of the beam splitter 150 can be expected. The number of times of sliding for shifting the laser irradiation position depends on the size of the beam splitter 150 and the size of the laser irradiation area, but is typically about 2 to 5 times.

The influence of the change in the element arrangement angle of the beam splitter 150 on the output light is small, and realignment for sliding only the beam splitter 150 is not necessary.

As a result, it is not necessary to replace the OPS module even when the beam splitter 150 is partially deteriorated, and the module usage time can be extended several times and the running cost can be suppressed.

Further, according to the configuration of the first embodiment, the beam splitter 150 can be slid while maintaining the sealing in the case 300, and downtime associated with the maintenance operation can be reduced.

### 5. Second Embodiment

### 5.1 Configuration

FIGS. 9 to 13 schematically show a slide mechanism 202 of the beam splitter 150 applied to the OPS of the laser device 2 according to the second embodiment. Instead of the slide mechanism 200 of the first embodiment described with reference to FIGS. 4 to 7, the slide mechanism 202 shown in FIGS. 9 to 13 may be employed. FIGS. 9 to 13 correspond to FIGS. 4 to 8, respectively. The configuration of the slide mechanism 202 of the second embodiment will be described in terms of differences from the slide mechanism 200 of the first embodiment.

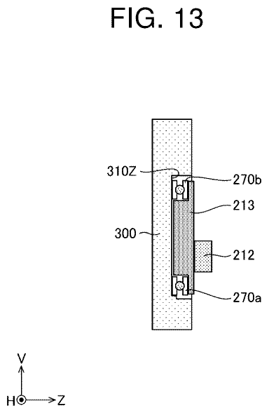

The slide mechanism 202 includes linear guides 270a, 270b instead of the plate holders 220a, 220b of the first embodiment (see FIG. 13).

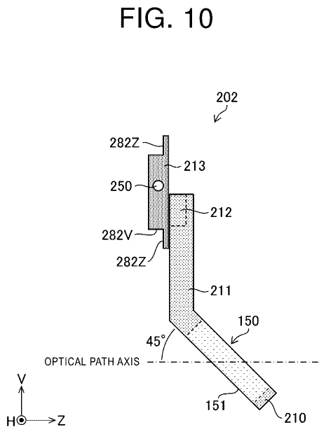

The linear guides 270a, 270b are arranged as being positioned on the reference surface 310Z of the case 300. The linear guides 270a, 270b are arranged parallel to the H direction. The plate 213 has a linear guide mounting surface 282Z and a linear guide mounting surface 282V (see FIG. 10). The linear guide mounting surface 282Z is a mounting surface perpendicular to the Z direction and engaged with Z-direction mounting surfaces of the linear guides 270a, 270b. The linear guide mounting surface 282V is a mounting surface perpendicular to the V direction and engaged with V-direction mounting surfaces of the linear guides 270a, 270b.

The plate 213 is slidably supported in the H direction by the linear guides 270a, 270b. Other configurations may be the same as those of the first embodiment. The linear guides 270a, 270b are examples of the “positioned member” in the present disclosure, and the Z-direction mounting surfaces and the V-direction mounting surfaces of the linear guides 270a, 270b are examples of the “reference surface of the member” in the present disclosure.

### 5.2 Operation

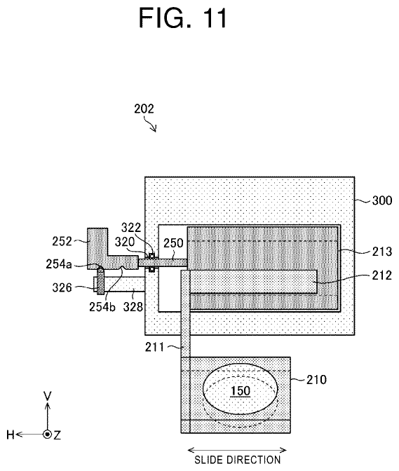

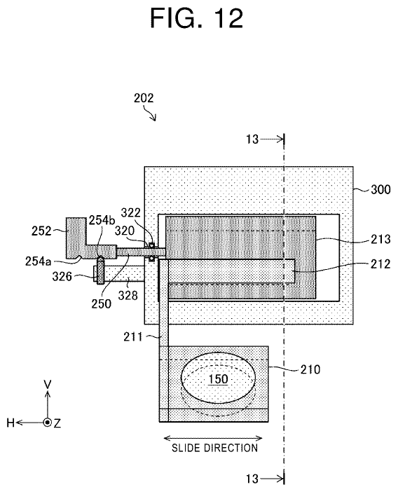

The operation of the slide mechanism 202 may be similar to the operation of the slide mechanism 200 of the first embodiment (see FIGS. 11 and 12).

### 5.3 Effect

According to the second embodiment, positioning can be performed with high accuracy in the V direction and the Z direction by the linear guides 270a, 270b. Further, an angle deviation between the optical surface 151 of the beam splitter 150 and the optical path axis can be suppressed during sliding.

### 6. Third Embodiment

### 6.1 Configuration

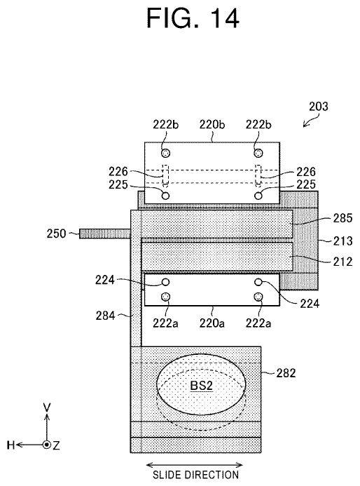

FIG. 14 is a view schematically showing a main part of a slide mechanism 203 applied to the OPS of the laser device 2 according to a third embodiment. The slide mechanism 203 is configured to move the two beam splitters BS1, BS2 of a two-stage OPS module at the same time.

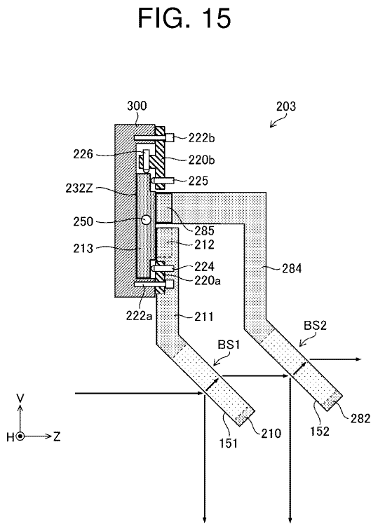

FIG. 15 is a side view including a partial section of the slide mechanism 203 viewed from the H direction. The configuration shown in FIGS. 14 and 15 will be described in terms of differences from the slide mechanism 200 described with reference to FIGS. 4 to 8.

In addition to the BS holder 210 holding the beam splitter BS1, the slide mechanism 203 includes a BS holder 282 holding the beam splitter BS2, a plate 284 fixing the BS holder 282, and a plate 285 fixing the plate 284 to the plate 213.

The beam splitter BS2 is arranged such that the optical surface 152 on which the laser light is incident is inclined by 45 degrees with respect to the optical path axis.

The BS holder 282 is fixed to the plate 284. The plate 284 is fixed to the plate 285. The plate 285 is fixed to the plate 213. Other configurations may be similar to those shown in FIGS. 4 to 8.

### 6.2 Operation

The plate 213 slides in a direction perpendicular to the optical path axis and parallel to the optical surface of the beam splitters BS1, BS2, so that the beam splitters BS1, BS2 slide simultaneously. Other operation may be similar to that of the first embodiment.

### 6.3 Effect

According to the configuration of the third embodiment, simultaneous sliding of the beam splitters BS1, BS2 enables the recovery with one operation when the beam splitters BS1, BS2 are deteriorated at substantially the same time.

According to the configuration of the third embodiment, it is not necessary to provide the slide mechanisms individually for the beam splitters BS1, BS2, and thus the configuration can be simplified.

### 6.4 Modification

In the configuration of the third embodiment, the configuration using the linear guides 270a, 270b described in the second embodiment may be adopted.

### 7. Fourth Embodiment

### 7.1 Configuration

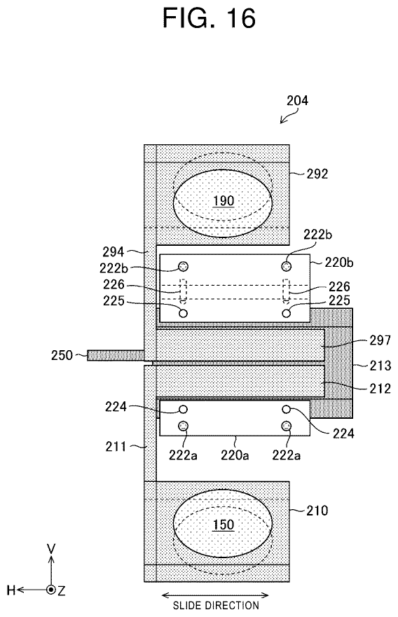

FIG. 16 is a view schematically showing a main part of a slide mechanism 204 applied to the OPS of the laser device 2 according to a fourth embodiment. Instead of the slide mechanism 200 of the first embodiment, the slide mechanism 204 may be employed. The slide mechanism 204 according to the fourth embodiment is configured such that a halving window 190 and the beam splitter 150 can be moved simultaneously. The combination of the halving window 190 and the beam splitter 150 may be the halving window HW1 and the beam splitter BS1 or may be the halving window HW2 and the beam splitter BS2 described with reference to FIG. 2.

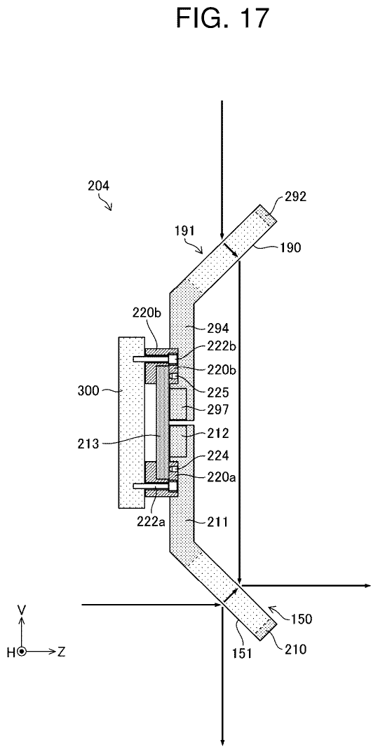

FIG. 17 is a side view including a partial section of the slide mechanism 204 viewed from the H direction. The configuration shown in FIGS. 16 and 17 will be described in terms of differences from the slide mechanism 200 described with reference to FIGS. 4 to 8.

The slide mechanism 204 includes a halving window holder 292 holding the halving window 190, a plate 294 fixing the halving window holder 292, and a plate 297 fixing the plate 294 to the plate 213.

The halving window 190 is arranged such that the optical surface 191 on which the laser light is incident is inclined by 45 degrees with respect to the optical path axis.

The halving window holder 292 is fixed to the plate 294. The plate 294 is fixed to the plate 297. The plate 297 is fixed to the plate 213. Other configurations may be similar to those shown in FIGS. 4 to 8. The halving window holder 292 is an example of the “second holder” in the present disclosure.

### 7.2 Operation

The plate 213 slides in a direction perpendicular to the optical path axis and parallel to the optical surface 151 of the beam splitter 150, so that the beam splitter 150 and the halving window 190 slide simultaneously.

### 7.3 Effect

According to the configuration of the fourth embodiment, simultaneous sliding of the beam splitter 150 and the halving window 190 enables the recovery with one operation when the beam splitter 150 and the halving window 190 are deteriorated at substantially the same time.

According to the configuration of the fourth embodiment, it is not necessary to provide the slide mechanisms individually for the beam splitter 150 and the halving window 190, and thus the configuration can be simplified.

### 7.4 Modification

In the configuration of the fourth embodiment, the configuration using the linear guides 270a, 270b described in the second embodiment may be adopted.

### 8. Fifth Embodiment

### 8.1 Configuration

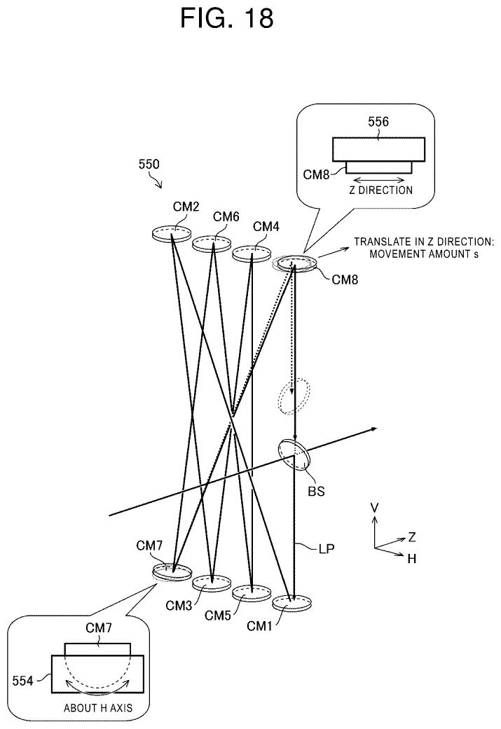

FIG. 18 is a perspective view schematically showing the configuration of an OPS 550 applied to the laser device 2 according to a fifth embodiment. The configuration shown in FIG. 18 will be described in terms of differences from the configuration shown in FIG. 2. Here, the configuration shown below is an example of the OPS 550 in which a loop optical path LP is formed by the beam splitter BS and eight concave mirrors CM1 to CM8. Instead of the first OPS module 510 described in FIG. 2, the OPS 550 shown in FIG. 18 may be applied. The eight concave mirrors CM1 to CM8 may have the similar configuration as the concave mirrors CM11 to CM18 described with reference to FIG. 2.

The loop optical path LP of the OPS 550 does not include the halving window HW1 compared to the loop optical path LP1 of the OPS module 510. Instead, the loop optical path LP includes a goniometer stage 554 or a tilt stage that changes the angle, about the H axis, of the concave mirror CM7 immediately before the final concave mirror CM8 in the loop optical path LP. The goniometer stage 554 or the tilt stage is an example of the “mirror angle adjustment mechanism” in the present disclosure.

Further, the OPS 550 includes a one-axis stage 556 that translates the final concave mirror CM8 in the loop optical path LP in the Z direction. Hereinafter, the final concave mirror CM8 in the loop optical path LP is referred to as the “final concave mirror CM8.” The concave mirror CM7 immediately before the final concave mirror CM8 is referred to as the “penultimate concave mirror CM7.”

Other configurations may be the same as those of the first embodiment.

### 8.2 Operation

In the OPS 550 according to the fifth embodiment, in order to combine the loop optical path LP and the transmission optical path of the beam splitter BS without using the halving window, the angle of the penultimate concave mirror CM7 is adjusted about the H axis by the goniometer stage 554 or the tilt stage, so that the incident position of the loop light on the final concave mirror CM8 is shifted by a predetermined distance.

Further, the position of the final concave mirror CM8 is translated by the one-axis stage 556 in the +Z direction by a predetermined distance.

With the loop optical path LP without using the halving window, the one-axis stage 556 preferably shifts the position of a light beam incident on the final concave mirror CM8 by a magnitude s according to Expression 1 below.

$$\begin{matrix}[ Expression 1 ] & \\ s = t \frac{sin ( θ - {θ}^{′} )}{cos ( {θ}^{′} )} & ( 1 )\end{matrix}$$

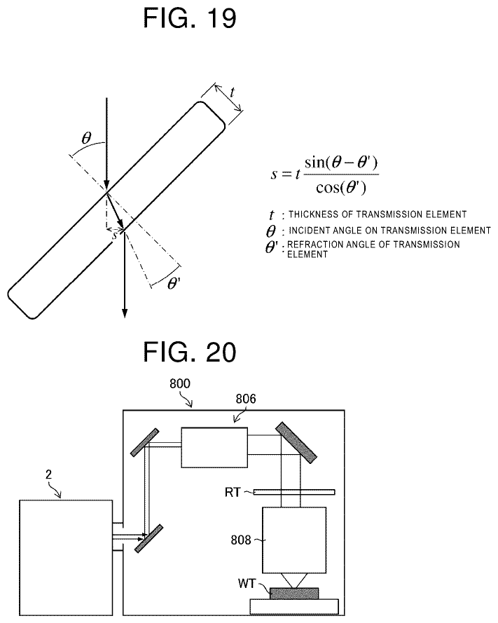

In Expression 1, t represents a thickness of a transmission element, θ represents an incident angle on the transmission element, and θ′ represents a refraction angle of the transmission element. Here, the transmission element is the halving window. FIG. 19 shows an explanatory diagram of the parameters of Expression 1. Exemplary values of the respective parameters are as follows. For example, a typical value of t is 7.0 mm, a typical value of θ is 45.0 deg, and a typical value of θ′ is 30.0 deg.

As shown in FIG. 19, the movement amount s for moving the final concave mirror CM8 in the +Z direction may be the same as the shift amount s of the laser optical path by the halving window (transmission element).

### 8.3 Effect

According to the OPS 550 of the fifth embodiment, since the optical path of the pulse laser light transmitted through the beam splitter BS and the loop optical path LP can be combined without arranging the halving window, there is no deterioration in the transmittance of the halving window as compared with the first embodiment. Thus, the number of elements necessary to be replaced due to deterioration can be reduced.

Further, since the arrangement position of the final concave mirror CM8 is translated by the amount corresponding to the deviation of the optical path, it is possible to reduce the risk of occurrence of vignetting due to irradiation of the light beam to the outside of the clear aperture of the mirror with the change of the optical path.

### 8.4 First Modification

Similarly, it is also possible to omit the halving window for the second OPS module 520. In this case, a goniometer stage or a tilt stage that changes the angle, about the H axis, of the concave mirror CM23 immediately before the final concave mirror CM24 of the loop optical path LP2 in FIG. 2 is arranged. Further, a one-axis stage that translates the final concave mirror CM24 in the Z direction is arranged.

### 8.5 Second Modification

As a mechanism for sliding the beam splitter BS in FIG. 18, the slide mechanism 200 described in the first embodiment or the slide mechanism 202 according to the second embodiment may be applied. In a case in which a two-stage OPS module is combined, the slide mechanism 203 according to the third embodiment may be applied.

### 9. Modification of Laser Device

Instead of the MO 10 shown in FIG. 1, for example, a solid-state laser system including a solid-state laser and a wavelength-conversion system may be employed. The wavelength conversion system may be configured using a nonlinear optical crystal. That is, the oscillation stage laser that generates seed light is not limited to a gas laser, and may be an ultraviolet solid-state laser that outputs pulse laser light having an ultraviolet wavelength. For example, the oscillation stage laser may be a solid-state laser that oscillates at a wavelength of about 193.4 nm, or an ultraviolet solid-state laser that outputs fourth harmonic light of a titanium-sapphire laser (wavelength of about 774 nm).

Further, not limited to the configuration including a Fabry-Perot resonator such as the MO 30 shown in FIG. 1, the amplifier may have a configuration including a ring resonator. Alternatively, the amplifier is not limited to the configuration including an optical resonator, and may be, for example, simply an excimer amplifier. The amplifier may be a multi-pass amplifier such as a three-pass amplifier that performs amplification by causing the seed light to pass through the discharge space three times with reflection by cylindrical mirrors.

### 10. Electronic Device Manufacturing Method

FIG. 20 schematically shows a configuration example of an exposure apparatus 800. The exposure apparatus 800 includes an illumination optical system 806 and a projection optical system 808. The laser device 2 generates laser light and outputs the laser light to the exposure apparatus 800. The illumination optical system 806 illuminates a reticle pattern of a reticle (not shown) arranged on a reticle stage RT with laser light incident from the laser device 2. The projection optical system 808 causes the laser light transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 800 synchronously translates the reticle stage RT and the workpiece table WT to expose the workpiece to the laser light reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

### 11. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser device comprising:
a pair of electrodes configured to cause discharge to occur; and
an optical pulse stretcher configured to extend a pulse width of pulse laser light generated by the discharge having occurred between the electrodes,
the optical pulse stretcher including:
a beam splitter arranged such that an optical surface thereof on which the pulse laser light is incident is inclined with respect to an optical path axis of the pulse laser light, and configured to separate the pulse laser light incident on the optical surface into reflection laser light and transmission laser light;
a plurality of mirrors configured to guide the reflection laser light to the beam splitter; and
a slide mechanism configured to move the beam splitter in a direction perpendicular to a direction of the discharge and parallel to the optical surface.

2. The laser device according to claim 1, further comprising a maintenance surface on which a maintenance panel capable of being opened and closed is formed,
wherein a direction in which the beam splitter is slid by the slide mechanism intersects the maintenance surface.

3. The laser device according to claim 1,
wherein the slide mechanism is capable of moving the beam splitter so that the pulse laser light is incident on a position different from a region in the optical surface of the beam splitter to which the pulse laser light has been radiated.

4. The laser device according to claim 1,
wherein, when a V direction represents a direction of the discharge, a Z direction represents a direction of the optical path axis of the pulse laser light incident on the optical surface of the beam splitter, and an H direction represents a direction perpendicular to the V direction and the Z direction, a slide direction of the beam splitter by the slide mechanism is parallel to the H direction.

5. The laser device according to claim 4,
wherein the slide mechanism includes a movable plate configured to slide in the H direction as being in contact with a first reference surface perpendicular to the Z direction and a second reference surface perpendicular to the V direction, and a rod configured to apply a force to the movable plate in the H direction, and
a first holder holding the beam splitter is fixed to the movable plate.

6. The laser device according to claim 5,
wherein the slide mechanism includes a first plunger urging the movable plate against the first reference surface and a second plunger urging the movable plate against the second reference surface.

7. The laser device according to claim 5,
wherein the optical pulse stretcher includes a case,
the beam splitter and the plurality of mirrors are arranged in the case, and
each of the first reference surface and the second reference surface serves as a reference surface for the case or a reference surface of a positioned member with respect to the reference surface of the case.

8. The laser device according to claim 7,
wherein the rod extends to outside the case.

9. The laser device according to claim 8,
wherein the case includes a through hole through which the rod penetrates, and
a seal member providing sealing inside the case is arranged at the through hole.

10. The laser device according to claim 5, further comprising a handle for operating the rod,
wherein a recessed portion causing the beam splitter to be positioned at a specific position in the slide direction is formed at the handle.

11. The laser device according to claim 10, further comprising a positioning plunger to engage with the recessed portion.

12. The laser device according to claim 5,
wherein the slide mechanism includes a first plate fixed to the first holder and a second plate fixed to the first plate, and
the second plate is fixed to the movable plate.

13. The laser device according to claim 5,
wherein the slide mechanism includes a linear guide slidably supporting the movable plate.

14. The laser device according to claim 1, further comprising a positioning mechanism restricting an arrangement position of the beam splitter in a slide direction in which the beam splitter is moved by the slide mechanism.

15. The laser device according to claim 14,
wherein the positioning mechanism includes an engaged member including a plurality of recessed portions including a first recessed portion causing the beam splitter to be located at a first position in the slide direction and a second recessed portion causing the beam splitter to be located at a second position in the slide direction, and a positioning plunger to engage with any one of the recessed portions.

16. The laser device according to claim 1,
wherein the optical pulse stretcher includes a plurality of the beam splitters, and
the slide mechanism moves the plurality of beam splitters simultaneously.

17. The laser device according to claim 1,
wherein the optical pulse stretcher includes a halving window arranged on an optical path through which the reflection laser light guided by the plurality of mirrors is returned to the beam splitter, and
the slide mechanism moves the beam splitter and the halving window simultaneously.

18. The laser device according to claim 5,
wherein the optical pulse stretcher includes a halving window arranged on an optical path through which the reflection laser light guided by the plurality of mirrors is returned to the beam splitter, and
a second holder holding the halving window is fixed to the movable plate.

19. The laser device according to claim 4,
wherein the optical pulse stretcher does not include a halving window on an optical path through which the reflection laser light is returned to the beam splitter by the plurality of mirrors, and includes a one-axis stage configured to move a final mirror among the plurality of mirrors in the Z direction, and a mirror angle adjustment mechanism configured to adjust an angle of a penultimate mirror among the plurality of mirrors.

20. An electronic device manufacturing method, comprising:
generating laser light with a pulse width extended using a laser device;
outputting the laser light to an exposure apparatus; and
exposing a photosensitive substrate to the laser light in the exposure apparatus to manufacture an electronic device,
the laser device including:
a pair of electrodes configured to cause discharge to occur; and
an optical pulse stretcher configured to extend the pulse width of pulse laser light generated by the discharge having occurred between the electrodes, and
the optical pulse stretcher including:
a beam splitter arranged such that an optical surface thereof on which the pulse laser light is incident is inclined with respect to an optical path axis of the pulse laser light, and configured to separate the pulse laser light incident on the optical surface into reflection laser light and transmission laser light;
a plurality of mirrors configured to guide the reflection laser light to the beam splitter; and
a slide mechanism configured to move the beam splitter in a direction perpendicular to a direction of the discharge and parallel to the optical surface.
